(19) United States
(12) Patent Application Publication
(10) Pub. No.: US 2023/0230816 A1
(43) Pub. Date: Jul. 20, 2023

(54) SEMICONDUCTOR DEVICE, SEMICONDUCTOR EQUIPMENT, AND SEMICONDUCTOR PROCESS METHOD

(71) Applicant: CHANGXIN MEMORY TECHNOLOGIES, INC., Hefei City (CN)

(72) Inventor: Zhiqiang LIU, Hefei City (CN)

(21) Appl. No.: 17/664,248

(22) Filed: May 20, 2022

Related U.S. Application Data
(63) Continuation of application No. PCT/CN2022/073836, filed on Jan. 25, 2022.

(30) Foreign Application Priority Data
Jan. 19, 2022 (CN) 202210060483.9

(51) Int. Cl. H01J 37/32; H01L 21/683

(52) U.S. Cl. CPC H01J 37/32697; H01J 37/32862; H01L 21/6831; H01J 2237/332; H01J 2237/334

(57) ABSTRACT

A semiconductor device, a semiconductor equipment, and a semiconductor process method. The semiconductor process method includes a phase of wafer adsorption and a phase of wafer release and charge release. The phase of wafer adsorption includes: a power supply unit outputting an operating voltage to an electrostatic chuck, so as to control the electrostatic chuck to adsorb a wafer. The phase of wafer release and charge release includes: adjusting a voltage outputted by the power supply unit from the operating voltage to a charge release voltage, and maintaining for a first preset time to release some of the charges accumulated on the electrostatic chuck so as to avoid abnormal discharge; and switching the electrostatic chuck to be connected to a protective resistor, and maintaining for a second preset time to release the remaining charges accumulated on the electrostatic chuck.

### CROSS-REFERENCE TO RELATED APPLICATIONS

This is a continuation of International Application No. PCT/CN2022/073836, filed on Jan. 25, 2022, which claims the priority to Chinese Patent Application No. 202210060483.9, filed with China National Intellectual Property Administration (CNIPA) on Jan. 19, 2022. The entire contents of International Application No. PCT/CN2022/073836 and Chinese Patent Application No. 202210060483.9 are incorporated herein by reference.

### TECHNICAL FIELD

The present disclosure relates to the technical field of semiconductor preparation processes, and in particular to a semiconductor device, a semiconductor equipment, and a semiconductor process method.

### BACKGROUND

In a plasma treatment device, an electrostatic chuck (ESC) is usually configured to fix a wafer, and a treatment gas and a specific electric field are introduced into a chamber, so that the treatment gas generates a plasma under the excitation of the electric field, to perform plasma treatment on the wafer. However, a film layer formed in a deposition process is easily attached to each of a side wall and a top of the chamber.

During a traditional plasma process, abnormal discharge is easy to occur in the treatment chamber in a process of de-energizing the electrostatic chuck, so that the film layers deposited on the side wall and the top wall of the chamber fall off, contamination particles are formed on the surface of the wafer, and influencing the yield of product.

### SUMMARY

A semiconductor device, a semiconductor equipment, and a semiconductor process method are provided according to various embodiments of the present application.

According to some embodiments, a first aspect of the present application provides a semiconductor device, including: a power supply unit, including a ground terminal and a voltage output terminal, and configured to provide an operating voltage and a charge release voltage, the charge release voltage being less than the operating voltage; an electrostatic chuck, connected to the power supply unit, and configured to adsorb a wafer when the power supply unit provides the operating voltage, charges being accumulated on the electrostatic chuck after the wafer is released; a protective resistor, connected to the ground terminal; and a relay unit, for connecting the electrostatic chuck to the power supply unit when the power supply unit provides the operating voltage, connecting, when the power supply unit provides the charge release voltage, the electrostatic chuck to the power supply unit for a preset time to release some of the charges accumulated on the electrostatic chuck so as to avoid abnormal discharge, and switching the electrostatic chuck to be connected to the protective resistor after the preset time.

According to some embodiments, a second aspect of the present application discloses a semiconductor equipment, including the semiconductor device in the foregoing embodiment.

According to some embodiments, a third aspect of the present application discloses a semiconductor process method. The method is applied to the semiconductor equipment in the foregoing embodiment, and includes a phase of wafer adsorption and a phase of wafer release and charge release. The phase of wafer adsorption includes: the power supply unit outputting the operating voltage to the electrostatic chuck, so as to control the electrostatic chuck to adsorb the wafer. The phase of wafer release and charge release includes: adjusting a voltage outputted by the power supply unit from the operating voltage to the charge release voltage, and maintaining for a first preset time to release some of the charges accumulated on the electrostatic chuck so as to avoid abnormal discharge; and switching the electrostatic chuck to be connected to the protective resistor, and maintaining for a second preset time to release the remaining charges accumulated on the electrostatic chuck.

Details of one or more embodiments of the present application will be illustrated in the following drawings and description. Other features, objectives, and advantages of the present application become evident in the specification, claims, and accompanying drawings.

### BRIEF DESCRIPTION OF THE DRAWINGS

To describe the technical solutions in the embodiments of the present application more clearly, the accompanying drawings required to describe the embodiments are briefly described below. Apparently, the accompanying drawings described below are only some embodiments of the present application. A person of ordinary skill in the art may further obtain accompanying drawings of other embodiments based on these accompanying drawings without creative efforts.

FIG. 1 is a schematic diagram of a circuit structure of a semiconductor device according to one embodiment of the present application.

FIG. 2 is a schematic diagram of a circuit structure in which an electrostatic chuck is connected to a power supply unit according to one embodiment of the present application.

FIG. 3 is a schematic diagram of a circuit structure in which an electrostatic chuck is connected to a protective resistor according to one embodiment of the present application.

FIG. 4 is a schematic diagram of a circuit structure of a semiconductor device according to another embodiment of the present application.

FIG. 5 is a schematic structural diagram of a semiconductor equipment according to one embodiment of the present application.

FIG. 6 is a flow block diagram of a semiconductor process method according to one embodiment of the present application.

### DETAILED DESCRIPTION

To facilitate the understanding of the present application, the present application will be described more completely below with reference to the accompanying drawings. Preferred embodiments of the present application are shown in the accompanying drawings. However, the present application may be embodied in various forms without being limited to the embodiments described herein. On the contrary, these embodiments are provided to make the present application more thorough and comprehensive.

Unless otherwise defined, all technical and scientific terms used herein have the same meaning as commonly understood by those skilled in the technical field of the present disclosure. The terms mentioned herein are merely for the purpose of describing specific embodiments, rather than to limit the present application. The term “and/or” used herein includes any and all combinations of one or more of the associated listed items.

In the description of a position relationship, unless otherwise specified, when one element, e.g., a layer substrate, is referred to as being “on” another film layer, it can be directly located on the other film layer or there may be an intermediate film layer. Further, when a layer is referred to as being “under” another layer, it can be directly under the other layer, or there may be one or more intermediate layers. It can also be understood that, when a layer is referred to as being “between” two layers, it may be the only layer between the two layers, or there may be one or more intermediate layers. The terms “on” and “under” in the present application refer to the degree of proximity of a haptic feedback module to a user in an application process, a side relatively close to the user is referred to as being “on”, and a side relatively distant from the user is referred to as being “under”.

In a case of using “include”, “have”, and “comprise” described herein, unless an explicit qualifying language is used, such as “only”, “consisting of”, etc., another component may also be added. Unless the contrary is mentioned, terms in the singular form may include the plural form but are not to be understood as a single one.

In the description of the present application, it should be noted that, unless otherwise clearly specified, the terms such as “interconnection”, or “connection” should be comprehended in a broad sense. For example, the “connection” may be a fixed connection, a detachable connection, or an integral connection; or may be a direct connection, an indirect connection via a medium, or internal communication within two elements. Those of ordinary skill in the art should understand the specific meanings of the above terms in the present application based on specific situations.

In addition, in the description of the present application, unless otherwise specified, the terms “multiple”, “mutually”, “overlapping”, “cascading”, and “several” mean two or more.

In a plasma process device, an electrostatic chuck (ESC) is usually configured to fix a wafer, and a treatment gas and a specific electric field are introduced into a chamber, so that the treatment gas generates a plasma under the excitation of the electric field, so as to perform a deposition process and an etching process on the wafer. However, after long-time use of the plasma process device, a film layer formed in the deposition process is easily attached to each of a side wall and a top of the chamber.

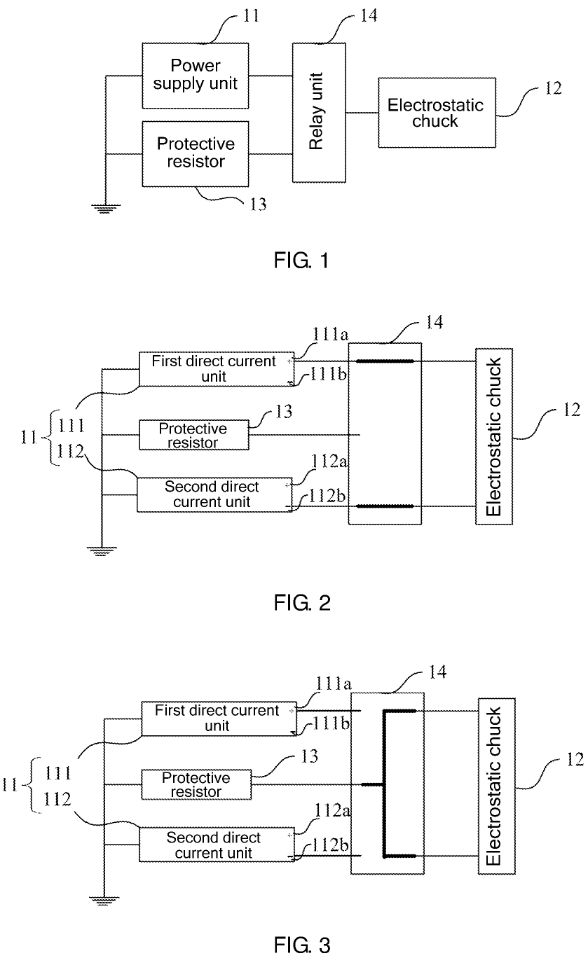

However, in a process of de-energizing the electrostatic chuck, arc discharge is easy to occur in the chamber of the plasma process device, and the wafer is damaged by an arc hitting the surface of the wafer. Moreover, after the arc hits the film layer attached to the side wall or the top of the chamber, contamination particles are generated and fall to the surface of the wafer, thereby influencing the yield of the wafer. To solve the above problems, one embodiment of the present application provides a semiconductor device. As shown in FIG. 1, the semiconductor device includes: a power supply unit 11 including a ground terminal and a voltage output terminal, and configured to provide an operating voltage and a charge release voltage, the charge release voltage being less than the operating voltage; an electrostatic chuck 12 connected to the power supply unit 11, and configured to adsorb the wafer when the power supply unit 11 provides the operating voltage, charges being accumulated on the electrostatic chuck 12 after the wafer is released; a protective resistor 13 connected to the ground terminal; and a relay unit 14 for connecting the electrostatic chuck 12 to the power supply unit 11 when the power supply unit 11 provides the operating voltage, connecting, when the power supply unit 11 provides the charge release voltage, the electrostatic chuck 12 to the power supply unit 11 for a preset time to release some of the charges accumulated on the electrostatic chuck 12 so as to avoid abnormal discharge, and switching the electrostatic chuck 12 to be connected to the protective resistor 13 after the preset time.

In the semiconductor device, the relay unit 14 and the power supply unit 11 cooperate with each other to keep the electrostatic chuck 12 connected to the power supply unit 11 within a preset time after the power supply unit 11 adjusts the operating voltage to the charge release voltage, so that a large amount of charges accumulated on the electrostatic chuck 12 can be quickly released first through a ground loop of the power supply unit 11. After a preset time, the electrostatic chuck 12 is connected to the protective resistor 13 to release the remaining charges, thereby reducing arc discharge caused by excessive charges and slow discharge at the beginning of discharge, reducing the damage to the surface of the wafer by the arc discharge, also reducing formation of impurity particles by an arc hitting the side wall of the reaction chamber, and improving the yield of the wafer.

Specifically, the power supply unit 11 may be a high-voltage direct-current unit, and may provide the operating voltage or the charge release voltage to the electrostatic chuck (ESC) 12. When the power supply unit 11 provides the operating voltage to the electrostatic chuck 12, the electrostatic chuck 12 can adsorb and fix the wafer placed on a surface thereof. However, when the power supply unit 11 provides the charge release voltage to the electrostatic chuck 12, the electrostatic chuck 12 does not adsorb the wafer anymore, so that the wafer can be moved to another position.

After the electrostatic chuck 12 releases the wafer, a large amount of charges are usually accumulated on the surface thereof. At this time, if the electrostatic chuck 12 is directly switched to the protective resistor 13 for grounding discharge, the arc discharge is very likely to occur to damage the surface of the wafer. Moreover, the arc discharge also easily knocks down the film layer attached to the side wall of the process chamber, and the film layer falls on the surface of the wafer to form contamination particles, which influences the yield of the wafer. To solve the above problems, the relay unit 14 in this embodiment can keep the electrostatic chuck 12 connected to the power supply unit 11 for a preset time when the power supply unit 11 is adjusted from the operating voltage to the charge release voltage. After the preset time, the electrostatic chuck 12 is switched to be connected to the protective resistor 13. Within a preset time after the power supply unit 11 is adjusted from the operating voltage to the charge release voltage, a large amount of charges accumulated on the electrostatic chuck 12 can be quickly released through the ground terminal of the power supply unit 11. After a preset time, most charges in the electrostatic chuck 12 are released. At this time, the electrostatic chuck 12 is switched to the protective resistor 13 for subsequent charge release, thereby greatly reducing a probability of arc discharge, reducing the damage to the surface of the wafer by the arc discharge or the hitting of the side wall of the reaction chamber, and improving the yield of the wafer.

In some embodiments, a resistance of an internal resistor of the power supply unit 11 is less than that of the protective resistor 13. For example, the resistance of the protective resistor 13 may be 3000 ohms to 5000 ohms, such as 3000 ohms, 3500 ohms, 4000 ohms, or 5000 ohms. The resistance of the power supply unit 11 may be 500 ohms to 1000 ohms, such as 500 ohms, 700 ohms, or 1000 ohms. By setting the resistance of the power supply unit 11 to be less than that of the protective resistor 13, a larger discharge current can be formed within a preset time after the operating voltage is adjusted to the charge release voltage, thereby accelerating the release of the charge.

In some embodiments, as shown in FIG. 2 and FIG. 3, the power supply unit 11 includes a first direct current unit 111 and a second direct current unit 112, the first direct current unit 111 includes a first positive output terminal 111a and a first negative output terminal 111b, the second direct current unit 112 includes a second positive output terminal 112a and a second negative output terminal 112b, and the first positive output terminal 111a and the second negative output terminal 112b jointly constitute the voltage output term inal of the power supply unit 11.

For example, in FIG. 2, when the power supply unit 11 provides the operating voltage, the first positive output terminal 111a of the first direct current unit 111 outputs a direct current voltage of +1.8 kV, the second negative output terminal 112b of the second direct current unit 112 outputs a direct current voltage of -1.8 kV, the power supply unit 11 outputs an operating voltage of 3.6 kV, and the electrostatic chuck 12 adsorbs and fixes the wafer.

For example, within the preset time after the power supply unit 11 is adjusted from the operating voltage to the charge release voltage, a circuit inside the relay unit 14 remains unchanged, so that the electrostatic chuck 12 and the power supply unit 11 are connected for a preset time. As shown in FIG. 2, a large amount of charges accumulated on the electrostatic chuck 12 can be quickly released through the ground terminal of the power supply unit 11. After the preset time, the circuit inside the relay unit 14 is adjusted to be a circuit shown in FIG. 3. The electrostatic chuck 12 is switched to be connected to the protective resistor 13. At this time, since most charges in the electrostatic chuck 12 are released, the probability of arc discharge is also greatly reduced even if the protective resistor 13 releases the charges in the electrostatic chuck 12. For example, the preset time may be 0.1 s, the charge release voltage may be 0 V, and both an output voltage of the first positive output terminal 111a of the first direct current unit 111 and an output voltage of the second negative output terminal 112b of the second direct current unit 112 are 0 V.

In some embodiments, the charge release voltage may be an any voltage value between 0 V and 200 V, such as 0 V, 10 V, 50 V, 100 V, 150 V, or 200 V. For example, the first positive output terminal 111a outputs a direct current voltage of +5 V, and the second negative output terminal 112b outputs a direct current voltage of -5 V; or the first positive output terminal 111a outputs a direct current voltage of +25 V, and the second negative output terminal 112b outputs a direct current voltage of -25 V. Optionally, the preset time may be an any time value between 0.1 s and 1 s, such as 0.1 s, 0.3 s, 0.5 s, or 1 s.

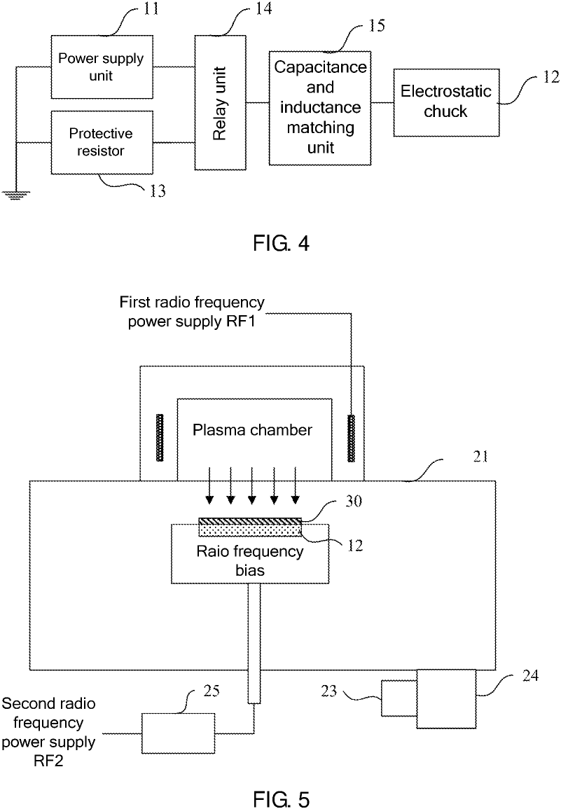

In some embodiments, as shown in FIG. 4, the semiconductor device further includes a capacitance and inductance matching unit 15 located between the relay unit 14 and the electrostatic chuck 12 and connected to the relay unit 14 and the electrostatic chuck 12. The capacitance and inductance matching unit 15 can transmit electric energy provided by the power supply unit 11 to the electrostatic chuck 12 to the greatest extent, so as to reduce the loss of electric energy.

One embodiment of the present application also discloses a semiconductor equipment, including the semiconductor device in the foregoing embodiment. As shown in FIG. 5, the semiconductor equipment may include a process chamber 21, in which the electrostatic chuck 12 is located and a wafer 30 is fixed. For example, the semiconductor equipment may be a plasma process equipment, such as an inductive coupled plasma (ICP) equipment. The plasma process equipment can perform a plasma process on the wafer 30, such as an argon plasma process or a hydrogen plasma process.

Specifically, the semiconductor equipment further includes a first radio frequency power supply RF1 and a second radio frequency power supply RF2. The first radio frequency power supply RF1 can generate a radio frequency power signal, and generate an induced electric field in the process chamber 21 through an induction coil, so as to excite a process gas which is introduced into the chamber into a plasma. The second radio frequency power supply RF2 is connected to the electrostatic chuck 12 that carries the wafer 30, and is configured to generate a negative bias on the surface of the wafer 30 to attract the plasma to move toward the wafer 30. Optionally, the semiconductor equipment further includes an impedance matcher 25 (RF match), and the second radio frequency power supply RF2 is connected to the electrostatic chuck 12 through the impedance matcher 25. The impedance matcher 25 is configured to reduce the loss of output power of the second radio frequency power supply RF2. For example, the first radio frequency power supply RF1 has an operating frequency of 12.5 Mhz, and the second radio frequency power supply RF2 has an operating frequency of 13.56 Mhz.

Please continue referring to FIG. 5, the semiconductor equipment further includes a cold trap 23 and a vacuum pump 24. The cold trap 23 may also be referred to as a cold trap chiller having a temperature that can be set as, for example, 120 K, and is configured to condense and adsorb water vapor generated in the process chamber 21. The vacuum pump 24 is configured to extract the gas and the plasma within the process chamber 21. The cold trap 23 and the vacuum pump 24 cooperate with each other, so that some particles, the water vapor, and the like generated in the process chamber 21 can be completely extracted to form a vacuum environment in the process chamber 21.

As an example, the hydrogen plasma process can be performed by using the semiconductor equipment shown in FIG. 5, and the complete process flow can refer to Table 1. In Table 1, Step represents a serial number of each step, Time represents a duration of each step, ESC represents the electrostatic chuck, RF1 represents the first radio frequency power supply, RF2 represents the second radio frequency power supply, the last column represents a hydrogen introduction velocity, and sccm represents a volumetric flow unit, namely a standard liter per minute.

TABLE 1

| Step | Time (sec) | ESC on | RF1 (W) | RF2 (W) | H2 (sccm) |
|---|---|---|---|---|---|
| 1 | 4 | Release | 0 | 0 | 0 |
| 2 | 1 | Release | 0 | 0 | 0 |
| 3 | 2 | Release | 0 | 0 | 0 |
| 4 | 11 | 1.6 kV-3.6 kV | 0 | 0 | 170 |
| 5 | 2 | 3.6 kV | 1900 | 0 | 170 |
| 6 | 1 | 3.6 kV | 1900 | 0 | 170 |
| 7 | 2 | 3.6 kV | 1900 | 450 | 170 |
| 8 | 10 | 3.6 kV | 1900 | 450 | 170 |
| 9 | 5 | 0 V→Release | 1900 | 0 | 170 |
| 10 | 2 | Release | 0 | 0 | 170 |
| 11 | 10 | Release | 0 | 0 | 0 |

Specifically, steps 1-3 form a phase of machine preparation in the hydrogen plasma process. It can be seen from Table 1 that in the phase of machine preparation, the electrostatic chuck 12 is always in a released state, and does not adsorb the wafer 30 yet. The first radio frequency power supply RF1 and the second radio frequency power supply RF2 are temporarily not powered on. At this time, hydrogen is not introduced into the process chamber 21, either. For example, the phase of machine preparation lasts for 7 s.

Starting from step 4, the power supply unit 11 starts to supply power to the electrostatic chuck 12 for fixing the wafer 30, and a power supply voltage is maintained between 1.6 kV and 3.6 kV. Moreover, the hydrogen starts to be introduced into the chamber in this phase, the process chamber 21 is fully filled with the hydrogen, and air in the process chamber 21 is completely exhausted. For example, the hydrogen introduction velocity may be 170 sccm. Optionally, the hydrogen introduction velocity can be adjusted according to process requirements.

In step 5 and step 6, the output voltage of the power supply unit 11 is stabilized at 3.6 kV. Moreover, the first radio frequency power supply RF1 is powered on to form the induced electric field in the process chamber 21, and the plasma is generated by using the hydrogen. For example, the operating power of the first radio frequency power supply RF1 may be 1900 W, and the frequency of the operating voltage is 12.5 Mhz. For example, step 5 and step 6 last for 3 s; and in this process, the hydrogen is continuously introduced into the process chamber 21 at a speed of 170 sccm.

In step 7 and step 8, the second radio frequency power supply RF2 is powered on for generating an adsorption electric field in the process chamber 21 to adsorb the plasma to the surface of the wafer 30. For example, the operating power of the second radio frequency power supply RF2 may be 450 W, and the frequency of the operating voltage is 13.56 Mhz. Step 7 and step 8 may last for, for example, 12 s; and in this process, the hydrogen is continuously introduced into the process chamber 21 at a speed of 170 sccm. Moreover, the first radio frequency power supply RF1 continuously provides the induced electric field with an operating power of 1900 W, and the power supply unit 11 continuously provides a high voltage direct current of 3.6 kV to the electrostatic chuck 12 to fix the wafer 30. The electrostatic chuck 12 accumulates a large amount of charges in this process.

Step 9 is a phase of charge release. In this phase, the second radio frequency power supply RF2 is stopped operating, there is no adsorption electric field in the process chamber 21 anymore, and the surface of the wafer 30 is not bombarded with the plasma anymore. The hydrogen is continuously introduced into the process chamber 21, and the first radio frequency power supply RF1 is also maintained in a normal operating state.

For example, the phase of charge release can be divided into a first phase and a second phase. In the first phase, the power supply unit 11 is kept connected to the electrostatic chuck 12, as shown in FIG. 2. The output voltage of the power supply unit 11 is a charge release voltage (for example, 0 V to 200 V). According to Table 1, the charge release voltage is 0 V. Therefore, the first positive output terminal 111a of the first direct current unit 111 outputs a voltage of 0 V, and the second negative output terminal 112b of the second direct current unit 112 outputs a voltage of 0 V.

As shown in FIG. 2, since an internal impedance of the power supply unit 11 is relatively small (much smaller than the resistance of the protective resistor 13), most of the charges accumulated on the electrostatic chuck 12 can be quickly released through the ground terminal of the power supply unit 11 in the first phase. The first phase may also be referred to as a phase of quick discharge. For example, the first phase lasts for 0.1 seconds.

The second phase may also be referred to as a phase of normal discharge. In the second phase, the relay unit 14 switches a circuit connection relationship, so as to switch the electrostatic chuck 12 to be connected to the protective resistor 13, as shown in FIG. 3. The charges remaining on the electrostatic chuck 12 are discharged through the protective resistor 13. For example, the second phase lasts for 4.9 s. Most of the charges accumulated on the electrostatic chuck 12 are released through the ground terminal of the power supply unit in the first phase. Therefore, after the electrostatic chuck 12 is connected to the protective resistor 13 in the second phase, the amount of charges on the electrostatic chuck 12 is not enough to generate the arc discharge, thereby reducing the probability of discharge, reducing the damage to the surface of the wafer 30 by the arc discharge, also reducing formation of impurity particles by an arc hitting the side wall of the reaction chamber, and improving the yield of the wafer 30.

In step 10, the first radio frequency power supply RF1 stops operating, without generating a plasma anymore. Moreover, the hydrogen is continuously introduced at a speed of 170 sccm, and the plasma remaining in the chamber is swept away by the continuously introduced hydrogen and evacuated by the vacuum pump 24. For example, step 10 lasts for 2 s.

Finally, the entire process flow is finished with step 11.

In other embodiments, when performing the plasma process by the semiconductor equipment shown in FIG. 5, a plasma gas can be selected, a duration of each step can be adjusted, and a duration of the first phase and a duration of the second phase in the phase of charge release can be adjusted according to actual needs.

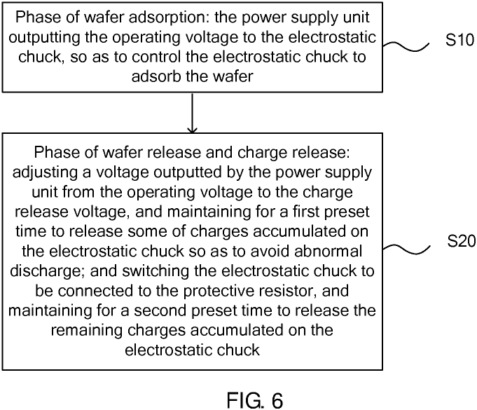

One embodiment of the present application also discloses a semiconductor process method. As shown in FIG. 6, the process is applied to the semiconductor equipment in the foregoing embodiment, and includes:

S10, a phase of wafer adsorption: the power supply unit 11 outputting the operating voltage to the electrostatic chuck 12, so as to control the electrostatic chuck 12 to adsorb the wafer; and

S20, a phase of wafer release and charge release: adjusting a voltage outputted by the power supply unit 11 from the operating voltage to the charge release voltage, and maintaining for a first preset time to release some of the charges accumulated on the electrostatic chuck 12 so as to avoid abnormal discharge; and switching the electrostatic chuck 12 to be connected to the protective resistor 13, and maintaining for a second preset time to release the remaining charges accumulated on the electrostatic chuck 12.

In step S10, the semiconductor equipment operates in the phase of wafer adsorption, the power supply unit 11 outputs an operating voltage of 3-4 kV to the electrostatic chuck 12, so as to control the electrostatic chuck 12 to adsorb the wafer. For example, the operating voltage may be 3,000 V, 3,600 V, or 4,000 V. For example, in the phase of wafer adsorption, the connection relationship between the power supply unit 11 and the electrostatic chuck 12 is as shown in FIG. 2.

In step S20, the semiconductor equipment operates in the phase of wafer release and charge release, the output voltage of the power supply unit 11 is adjusted from the operating voltage to the charge release voltage and maintained for a first preset time. For example, the charge release voltage may be 0-200 V, such as 0 V, 10 V, 50 V, 100 V, 150 V, or 200 V. The first preset time may be 0.1-1 seconds, such as 0.1 seconds, 0.2 seconds, 0.5 seconds, or 1 second. Within the first preset time, although the output voltage of the power supply unit is adjusted from the operating voltage to the charge release voltage, the connection relationship between the power supply unit 11 and the electrostatic chuck 12 is still as shown in FIG. 2. At this time, a voltage generated by the charges accumulated on the electrostatic chuck 12 is much larger than the charge release voltage provided by the power supply unit 11. Moreover, since the internal impedance of the power supply unit 11 is relatively small, the charges accumulated on the electrostatic chuck 12 can be quickly released through the ground terminal of the power supply unit 11.

After the first preset time, the electrostatic chuck 12 is switched to be connected to the protective resistor 13 and maintained for a second preset time, as shown in FIG. 3. At this time, since most charges in the electrostatic chuck 12 are released through the ground terminal of the power supply unit 11, and a voltage that can be generated by the charges remaining in the electrostatic chuck 12 is greatly reduced, the arc discharge due to a too large resistance of the protective resistor 13 cannot occur even if the electrostatic chuck 12 is connected to the protective resistor 13 for charge release. For example, the second preset time may be 4-4.9 seconds, such as 4 seconds, 4.5 seconds, 4.8 seconds, or 4.9 seconds.

In the semiconductor process method, the electrostatic chuck 12 is first kept connected to the power supply unit 11 in the phase of wafer release and charge release and maintained for the first preset time, so that most of the charges accumulated on the electrostatic chuck 12 are released through the ground terminal of the power supply unit 11. Since the resistance of the internal resistor of the power supply unit 11 is smaller than the resistance of the protective resistor 13, the discharge current is larger, and a large amount of charges can be released in a short time. After the first preset time, the electrostatic chuck 12 is switched to the protective resistor 13 for releasing the remaining charges. At this time, a large amount of charges are released, thereby greatly reducing the probability of arc discharge, reducing the damage to the surface of the wafer by the arc discharge, also reducing formation of impurity particles by an arc hitting an impurity layer adhered to the side wall of the reaction chamber, and improving the yield of the wafer. Moreover, since the probability of arc discharge is reduced, a downtime to deal with a fault can be reduced, and smooth production of the product can be ensured.

In some embodiments, a sum of the first preset time and the second preset time is a fixed value, such as 5 seconds.

In some embodiments, a process phase is also included between the phase of wafer adsorption and the phase of wafer release and charge release, and includes: performing a process operation on the wafer. For example, the process operation may include: bombarding the wafer with a plasma. For example, the surface of the wafer can be bombarded with the plasma to remove a specific film layer or impurities on the surface of the wafer. The plasma may be a hydrogen plasma, an argon plasma, or other plasmas.

Optionally, the process operation may further include a plasma deposition process for depositing a film layer on the surface of the wafer.

In some embodiments, a phase of equipment preparation is further included before the phase of wafer adsorption. The phase of equipment preparation may be, for example, to introduce a protective gas into a process chamber 21, and the protective gas may be an inert gas, argon, or hydrogen. By introducing the protective gas into the process chamber 21, air in the process chamber 21 can be evacuated to form an oxygen-free environment in the process chamber 21, so as to avoid oxidation.

In some embodiments, a phase of cleaning is also included after the phase of wafer release and charge release, and includes: introducing a cleaning gas into the process chamber to clean the process chamber. For example, each of the protective gas and the cleaning gas is a reducing gas, such as hydrogen.

For example, the semiconductor process method can be applied to, for example, a ULVAC Entron EX-W300 equipment or a process chamber of ENI/2000 with ENI1250. According to the semiconductor process method, a best hydrogen plasma process flow provided by some ICP equipment manufacturers can be improved, thereby reducing the probability of arc discharge in the electrostatic chuck during the phase of wafer release, and improving the yield of product.

The technical features of the above embodiments can be employed in arbitrary combinations. To provide a concise description, all possible combinations of all technical features of the above embodiments may not be described; however, these combinations of technical features should be construed as disclosed in this specification as long as no contradiction occurs.

Only several implementations of the present application are described in detail in the foregoing embodiments, but they should not therefore be construed as limiting the scope of the present application. It should be noted that those of ordinary skill in the art can further make variations and improvements without departing from the conception of the present disclosure. These variations and improvements all fall within the protection scope of the present disclosure. Therefore, the protection scope of the present application should be subject to the protection scope defined by the claims.

1. A semiconductor device, comprising:
a power supply unit, comprising a ground terminal and a voltage output terminal, and configured to provide an operating voltage and a charge release voltage, the charge release voltage being less than the operating voltage;
an electrostatic chuck, connected to the power supply unit, and configured to adsorb a wafer when the power supply unit provides the operating voltage, charges being accumulated on the electrostatic chuck after the wafer is released;
a protective resistor, connected to the ground terminal; and
a relay unit, for connecting the electrostatic chuck to the power supply unit when the power supply unit provides the operating voltage, connecting, when the power supply unit provides the charge release voltage, the electrostatic chuck to the power supply unit for a preset time to release some of the charges accumulated on the electrostatic chuck so as to avoid abnormal discharge, and switching the electrostatic chuck to be connected to the protective resistor after the preset time.

2. The semiconductor device according to claim 1, wherein a resistance of the power supply unit is less than a resistance of the protective resistor.

3. The semiconductor device according to claim 2, wherein the resistance of the protective resistor ranges from 3,000 ohms to 5,000 ohms.

4. The semiconductor device according to claim 1, wherein the power supply unit comprises a first direct current unit and a second direct current unit, each of the first direct current unit and the second direct current unit comprises a positive output terminal and a negative output terminal, and the positive output terminal of the first direct current unit and the negative output terminal of the second direct current unit jointly constitute the voltage output terminal.

5. The semiconductor device according to claim 1, further comprising a capacitance and inductance matching unit, located between the relay unit and the electrostatic chuck and connected to the relay unit and the electrostatic chuck.

6. A semiconductor equipment, comprising the semiconductor device according to claim 1.

7. The semiconductor equipment according to claim 6, further comprising a process chamber, in which the electrostatic chuck is located.

8. The semiconductor equipment according to claim 6, further comprising a plasma process equipment.

9. A semiconductor process method, applied to the semiconductor equipment according to claim 6, wherein the method comprises a phase of wafer adsorption and a phase of wafer release and charge release;
the phase of wafer adsorption comprises: the power supply unit outputting the operating voltage to the electrostatic chuck, so as to control the electrostatic chuck to adsorb the wafer; and
the phase of wafer release and charge release comprises:
adjusting a voltage outputted by the power supply unit from the operating voltage to the charge release voltage, and maintaining for a first preset time to release some of the charges accumulated on the electrostatic chuck so as to avoid abnormal discharge;
and switching the electrostatic chuck to be connected to the protective resistor, and maintaining for a second preset time to release the remaining charges accumulated on the electrostatic chuck.

10. The semiconductor process method according to claim 9, wherein the operating voltage ranges from 3 kV to 4 kV, and the charge release voltage ranges from 0 V to 200 V.

11. The semiconductor process method according to claim 9, wherein the first preset time ranges from 0.1 seconds to 1 second, and the second preset time ranges from 4 seconds to 4.9 seconds.

12. The semiconductor process method according to claim 9, further comprising a process phase between the phase of wafer adsorption and the phase of wafer release and charge release, wherein the process phase comprises: performing a process operation on the wafer.

13. The semiconductor process method according to claim 12, wherein the process operation comprises: bombarding the wafer with a plasma.

14. The semiconductor process method according to claim 12, wherein the semiconductor equipment further comprises a process chamber, in which the electrostatic chuck is located; the semiconductor process method further comprises a phase of equipment preparation before the phase of wafer adsorption, and the phase of equipment preparation comprises: introducing a protective gas into the process chamber.

15. The semiconductor process method according to claim 14, further comprising a phase of cleaning after the phase of wafer release and charge release, wherein the phase of cleaning comprises: introducing a cleaning gas into the process chamber to clean the process chamber.

16. The semiconductor process method according to claim 15, wherein each of the protective gas and the cleaning gas comprises a reducing gas.
